(19) United States
(12) Patent Application Publication
(10) Pub. No.: US 2024/0179947 A1
(43) Pub. Date: May 30, 2024

(54) DISPLAY APPARATUS AND METHOD OF MANUFACTURING THE SAME

(71) Applicant: Samsung Display Co., Ltd., Yongin-si (KR)

(72) Inventors: Pilgyu Kang, Yongin-si (KR); Younghoon Yoo, Yongin-si (KR); Euna Yu, Yongin-si (KR); Jeonghyun Lee, Yongin-si (KR); Hanul Lee, Yongin-si (KR); Sangcheon Han, Yongin-si (KR)

(73) Assignee: Samsung Display Co., Ltd., Yongin-si (KR)

(21) Appl. No.: 18/454,310

(22) Filed: Aug. 23, 2023

(30) Foreign Application Priority Data
Nov. 29, 2022 (KR) 10-2022-0163247

(51) Int. Cl. H10K 59/121; H10K 59/12

(52) U.S. Cl. CPC H10K 59/1213; H10K 59/1201

(57) ABSTRACT

A display apparatus includes a semiconductor layer disposed on a substrate and including a channel area, a source area and a drain area that are disposed at both sides of the channel area, and a first opening portion disposed adjacent to the source area or the drain area, and a first electrode overlapping and electrically connected to the source area or the drain area and including an edge adjacent to the first opening portion. The edge of the first electrode is concave in a direction from the first opening portion toward the source area or the drain area.

### CROSS-REFERENCE TO RELATED APPLICATION(S)

This application claims priority to and benefits of Korean Patent Application No. 10-2022-0163247 under 35 U.S.C. § 119, filed on Nov. 29, 2022 in the Korean Intellectual Property Office, the entire contents of which are incorporated herein by reference.

### BACKGROUND

### 1. Technical Field

One or more embodiments relate to a display apparatus and a method of manufacturing the same.

### 2. Description of the Related Art

A display apparatus is an apparatus that visually displays data. A display apparatus may be used as a display of a small-sized product, such as a cellular phone, or a display of a large-sized product, such as a television.

A display apparatus may include a liquid-crystal display apparatus that does not directly emit light but uses light of a backlight device, or may include a light-emitting display apparatus including a display element that may emit light, wherein the display element may include an emission layer.

### SUMMARY

One or more embodiments include a display apparatus including a high quality transistor and a method of manufacturing the display apparatus. However, this aspect is an example and does not limit the scope of the disclosure.

Additional aspects will be set forth in part in the description which follows and, in part, will be apparent from the description, or may be learned by practice of the embodiments of the disclosure.

According to one or more embodiments, a display apparatus may include a semiconductor layer disposed on a substrate and including a channel area, a source area and a drain area that are disposed at both sides of the channel area, and a first opening portion disposed adjacent to the source area or the drain area, and a first electrode overlapping and electrically connected to the source area or the drain area and including an edge adjacent to the first opening portion. The edge of the first electrode may be concave in a direction from the first opening portion toward the source area or the drain area.

The edge of the first electrode may have an arc shape.

The edge of the first electrode may include a first sub-edge of the first electrode, and a second sub-edge of the first electrode, the first sub-edge of the first electrode and the second sub-edge of the first electrode may extend in a first direction and a second direction, respectively, and the first sub-edge of the first electrode and the second sub-edge of the first electrode may intersect each other.

An edge of the first opening portion that is adjacent to the first electrode may be protrusive in a direction toward the source area or the drain area.

The edge of the first opening portion that is adjacent to the first electrode may have an arc shape.

The edge of the first opening portion that is adjacent to the first electrode may include a first sub-edge of the first opening portion, and a second sub-edge of the first opening portion, the first sub-edge of the first opening portion and the second sub-edge of the first opening portion may extend in a first direction and a second direction, respectively, and the first sub-edge of the first opening portion and the second sub-edge of the first opening portion may intersect each other.

A portion of the semiconductor layer may be disposed between the edge of the first electrode and the first opening portion.

The display apparatus may further include an insulating pattern layer disposed between the semiconductor layer and the first electrode.

The insulating pattern layer may partially surround the first electrode. The first electrode may partially overlap the source area or the drain area of the semiconductor layer, and a portion of the semiconductor layer may be exposed, due to the insulating pattern layer.

The display apparatus may further include a second electrode overlapping and electrically connected to the source area or the drain area. The semiconductor layer may further include a second opening portion disposed adjacent to the source area or the drain area, and an edge of the second electrode may be concave in a direction from the second opening portion toward the source area or the drain area.

According to one or more embodiments, a method of manufacturing a display apparatus may include forming, on a substrate, a semiconductor layer including a channel area, and a source area and a drain area at both sides of the channel area, forming, on the semiconductor layer, a material for forming an electrode, forming a first photoresist on the material for forming the electrode, and forming a first electrode by etching the material for forming the electrode. In case that the material for forming the electrode is etched, at least a portion of the semiconductor layer may be etched resulting in a first opening portion being formed at a location adjacent to the source area or the drain area. An edge of the first electrode may be formed to be concave in a direction from the first opening portion toward the source area or the drain area.

The method may further include, after the forming of the first electrode by etching the material for forming the electrode, removing the first photoresist.

The edge of the first electrode may have an arc shape.

The edge of the first electrode may include a first sub-edge of the first electrode, and a second sub-edge of the first electrode, the first sub-edge of the first electrode and the second sub-edge of the first electrode may extend in a first direction and a second direction, respectively, and the first sub-edge of the first electrode and the second sub-edge of the first electrode may intersect each other.

An edge of the first photoresist may be formed to be concave in a direction from the channel area of the semiconductor layer toward the source area or the drain area of the semiconductor layer.

The edge of the first photoresist may have an arc shape.

The edge of the first photoresist may include a first sub-edge of the first photoresist, and a second sub-edge of the first photoresist, the first sub-edge of the first photoresist and the second sub-edge of the first photoresist may extend in a first direction and a second direction, respectively, and the first sub-edge of the first photoresist and the second sub-edge of the first photoresist may intersect each other.

The forming of the semiconductor layer including the source area and the drain area may include forming, on the substrate, a material for forming a semiconductor layer, forming the semiconductor layer by patterning the material for forming the semiconductor layer, forming an inorganic insulating layer on the semiconductor layer, and forming a plurality of holes by etching at least a portion of the inorganic insulating layer. In case that the plurality of holes are formed, an exposed portion of the semiconductor layer may become conductive.

The method may further include forming an insulating pattern layer by etching the inorganic insulating layer disposed between the semiconductor layer and the first electrode.

The method may further include forming a second photoresist on the material for forming the electrode, and forming, on the semiconductor layer, a second electrode by etching the material for forming the electrode. In case that the material for forming the electrode is etched, at least a portion of the semiconductor layer may be etched resulting in a second opening portion being formed at a location adjacent to the source area or the drain area, and an edge of the second electrode may be formed to be concave in a direction from the second opening portion toward the source area or the drain area.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 is a schematic cross-sectional view of each of pixels of a display apparatus, according to an embodiment;

FIG. 3 is a schematic view of each of optical portions of a color-conversion-transmission layer of FIG. 2;

FIG. 4 is a schematic diagram of an equivalent circuit of a light-emitting diode included in a display apparatus and a pixel circuit electrically connected to the light-emitting diode, according to an embodiment;

FIG. 5 is a schematic cross-sectional view of a display apparatus according to an embodiment;

FIGS. 6 and 7 are schematic plan views of a display apparatus according to embodiments;

FIG. 8 shows schematic cross-sectional views of the display apparatus of FIG. 7, according to an embodiment;

FIG. 9 is a schematic cross-sectional view of an enlarged portion of a first opening portion of FIG. 7; and

FIGS. 10A to 15C are schematic views for describing a method of manufacturing a display apparatus, according to embodiments.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

It will be understood that although the terms “first,” “second,” etc. may be used herein to describe various components, these components should not be limited by these terms. These components are only used to distinguish one component from another.

As used herein, the singular expressions “a,” “an,” and “the” are intended to include the plural forms as well, unless the context clearly indicates otherwise.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be understood that when a layer, region, or element is referred to as being formed “on” another layer, area, or element, it can be directly or indirectly formed on the other layer, region, or element. For example, intervening layers, regions, or elements may be present.

Sizes of elements in the drawings may be exaggerated for convenience of explanation. For example, sizes and thicknesses of the elements in the drawings may be randomly indicated for convenience of explanation, and thus, the disclosure is not necessarily limited to the illustrations of the drawings.

When a certain embodiment may be implemented differently, a specific process order may be performed differently from the described order. For example, two consecutively described processes may be performed substantially at the same time or performed in an order opposite to the described order.

In the embodiments hereinafter, it will be understood that when an element, an area, or a layer is referred to as being connected to another element, area, or layer, it can be directly and/or indirectly connected to the other element, area, or layer.

It will be understood that the terms “connected to” or “coupled to” may include a physical and/or electrical connection or coupling.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

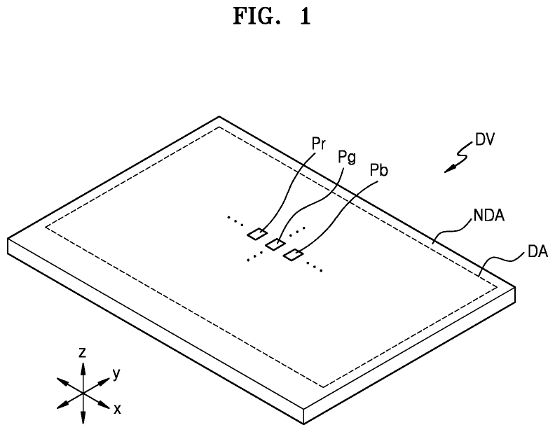

FIG. 1 is a schematic perspective view of a display apparatus DV according to an embodiment.

Referring to FIG. 1, the display apparatus DV may include a display area DA and a non-display area NDA outside the display area DA. The display apparatus DV may provide an image through an array of multiple pixels that are two-dimensionally arranged on an x-y plane in the display area DA. The pixels may include a first pixel, a second pixel, and a third pixel. Hereinafter, for convenience of explanation, descriptions will be given based on a case in which the first pixel is a red pixel Pr, the second pixel is a green pixel Pg, and the third pixel is a blue pixel Pb.

The red pixel Pr, the green pixel Pg, and the blue pixel Pb may be areas for emitting red light, green light, and blue light, respectively, and the display apparatus DV may provide an image by using the light emitted from the pixels.

The non-display area NDA may be an area which may not provide an image, and the non-display area NDA may entirely surround the display area DA. A driver or a main voltage line configured to provide electrical signals or power to pixel circuits may be arranged in the non-display area NDA. The non-display area NDA may include a pad, which is an area, to which an electronic device or a printed circuit board may be electrically connected.

The display area DA may have a polygonal shape including a quadrangular shape as illustrated in FIG. 1. For example, the display area DA may have a rectangular shape having a horizontal length that is greater than a vertical length, a rectangular shape having a horizontal length that is less than a vertical length, or a square shape. In other embodiments, the display area DA may have various shapes, for example, an oval shape or a circular shape.

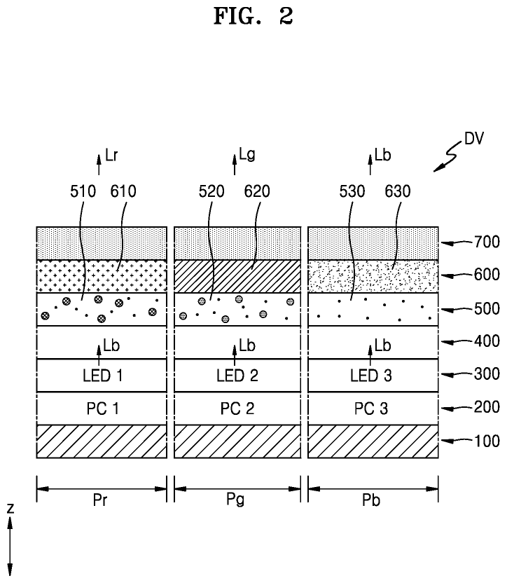

FIG. 2 is a schematic cross-sectional view of each of the pixels of the display apparatus DV, according to an embodiment.

Referring to FIG. 2, the display apparatus DV may include a circuit layer 200 on a substrate 100. The circuit layer 200 may include a first pixel circuit PC1, a second pixel circuit PC2, and a third pixel circuit PC3, and the first through third pixel circuits PC1 through PC3 may be electrically connected to a first light-emitting diode LED1, a second light-emitting diode LED2, and a third light-emitting diode LED3 of a light-emitting diode layer 300, respectively.

The first through third light-emitting diodes LED1 through LED3 may include organic light-emitting diodes including organic materials. According to another embodiment, the first through third light-emitting diodes LED1 through LED3 may include inorganic light-emitting diodes including inorganic materials. An inorganic light-emitting diode may include a PN junction diode including inorganic semiconductor-based materials. In case that a voltage is applied to the PN junction diode in a normal direction, holes and electrons may inject into the PN junction diode, and energy generated by recombination of the holes and the electrons may convert into light energy to emit a certain color of light. The inorganic light-emitting diode described above may have a width that is several to hundreds of micrometers or several to hundreds of nanometers. According to some embodiments, the light-emitting diode LED may include a light-emitting diode including quantum dots. As described above, an emission layer of the light-emitting diode LED may include an organic material, an inorganic material, quantum dots, an organic material and quantum dots, and/or an inorganic material and quantum dots.

The first through third light-emitting diodes LED1 through LED3 may emit the same color of light. For example, light (for example, blue light Lb) emitted from the first through third light-emitting diodes LED1 through LED3 may be transmitted through the color-conversion-transmission layer 500 by passing through an encapsulation layer 400 on the light-emitting diode layer 300.

The color-conversion-transmission layer 500 may include optical portions configured to transmit the light (for example, the blue light Lb) emitted from the light-emitting diode layer 300 by converting or without converting the color of light. For example, the color-conversion-transmission layer 500 may include color-conversion portions configured to convert the light (for example, the blue light Lb) emitted from the light-emitting diode layer 300 into another color of light and a transmission portion configured to transmit the light (for example, the blue light Lb) emitted from the light-emitting diode layer 300 without converting the color of light. The color-conversion-transmission layer 500 may include a first color-conversion portion 510 corresponding to a red pixel Pr, a second color-conversion portion 520 corresponding to a green pixel Pg, and a transmission portion 530 corresponding to a blue pixel Pb. The first color-conversion portion 510 may convert the blue light Lb into red light Lr, and the second color-conversion portion 520 may convert the blue light Lb into green light Lg. The transmission portion 530 may transmit the blue light Lb without converting the color of light.

A color layer 600 may be arranged on the color-conversion-transmission layer 500. The color layer 600 may include a first color filter 610, a second color filter 620, and a third color filter 630 having different colors from one another. For example, the first color filter 610 may be a red color filter, the second color filter 620 may be a green color filter, and the third color filter 630 may be a blue color filter.

The light having the color converted by the color-conversion-transmission layer 500 or the light transmitted by the color-conversion-transmission layer 500 may have an improved color purity by passing through the first through third color filters 610 through 630. The color layer 600 may prevent or minimize the phenomenon that the external light (for example, light that is incident toward the display apparatus DV from the outside of the display apparatus DV) is reflected and viewed by a user.

A transmissive substrate layer 700 may be provided on the color layer 600. The transmissive substrate layer 700 may include glass or a transmissive organic material. For example, the transmissive substrate layer 700 may include a transmissive organic material, such as acryl-based resins.

According to an embodiment, the transmissive substrate layer 700 may include a type of substrate. After the color layer 600 and the color-conversion-transmission layer 500 are provided on the transmissive substrate layer 700, the transmissive substrate layer 700 may be integrally formed with the color layer 600 and the color-conversion-transmission layer 500 such that the color-conversion-transmission layer 500 may face the encapsulation layer 400.

According to another embodiment, after the color-conversion-transmission layer 500 and the color layer 600 are sequentially formed on the encapsulation layer 400, the transmissive substrate layer 700 may be directly coated and cured on the color layer 600. According to some embodiments, another optical film, for example, an anti-reflection (AR) film, etc., may be arranged on the transmissive substrate layer 700.

The display apparatus DV having the structure described above may include an electronic device capable of displaying a video or a still image, such as a television, a billboard, a movie theater screen, a monitor, a tablet personal computer (PC), a notebook computer, etc.

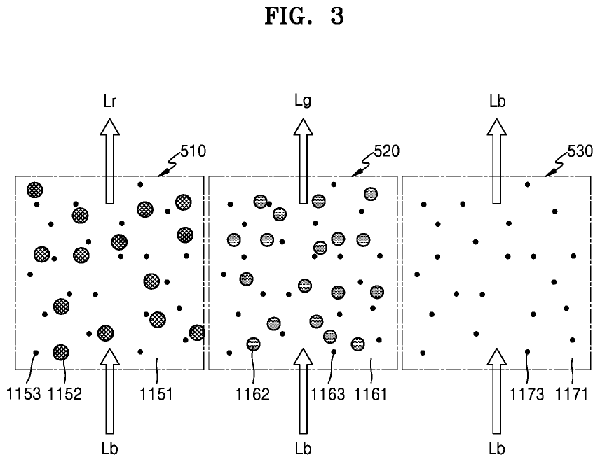

FIG. 3 schematically illustrates each of the optical portions of the color-conversion-transmission layer 500 of FIG. 2.

Referring to FIG. 3, the first color-conversion portion 510 may convert incident blue light Lb into red light Lr. As illustrated in FIG. 3, the first color-conversion portion 510 may include a first photo-sensitive polymer 1151, first quantum dots 1152 and first scattering particles 1153, wherein the first quantum dots 1152 and the first scattering particles 1153 are distributed in the first photo-sensitive polymer 1151.

The first quantum dots 1152 may be excited by the blue light Lb and may emit the red light Lr having a greater wavelength than the blue light Lb in an isotropic fashion. The first photo-sensitive polymer 1151 may include a light-transmissive organic material. The first scattering particles 1153 may scatter the blue light Lb not absorbed by the first quantum dots 1152 to excite more first quantum dots 1152, thereby improving the color-conversion efficiency. The first scattering particles 1153 may include, for example, oxide titanium (TiO2) or metal particles. The first quantum dots 1152 may be selected from a Groups II-VI compound, a Groups III-V compound, a Groups IV-VI compound, a Group IV element, a Group IV compound, and a combination thereof.

The second color-conversion portion 520 may convert incident blue light Lb into green light Lg. As illustrated in FIG. 3, the second color-conversion portion 520 may include a second photo-sensitive polymer 1161, second quantum dots 1162 and second scattering particles 1163, wherein the second quantum dots 1162 and the second scattering particles 1163 are distributed in the second photo-sensitive polymer 1161.

The second quantum dots 1162 may be excited by the blue light Lb and may emit the green light Lg having a greater wavelength than the blue light Lb in an isotropic fashion. The second photo-sensitive polymer 1161 may include a light-transmissive organic material.

The second scattering particles 1163 may scatter the blue light Lb not absorbed by the second quantum dots 1162 to excite more second quantum dots 1162, thereby improving the color-conversion efficiency. The second scattering particles 1163 may include, for example, TiO2 or metal particles. The second quantum dots 1162 may be selected from a Groups II-VI compound, a Groups III-V compound, a Groups IV-VI compound, a Group IV element, a Group IV compound, and a combination thereof.

The transmission portion 530 may transmit the blue light Lb that is incident into the transmission portion 530 without converting the color of the blue light Lb. As illustrated in FIG. 3, the transmission portion 530 may include a third photo-sensitive polymer 1171 in which third scattering particles 1173 are distributed. The third photo-sensitive polymer 1171 may include a light-transmissive organic material, such as silicon resins, epoxy resins, etc., and may include the same material as the first and second photo-sensitive polymers 1151 and 1161. The third scattering particles 1173 may scatter and emit the blue light Lb and may include the same material as the first and second scattering particles 1153 and 1163.

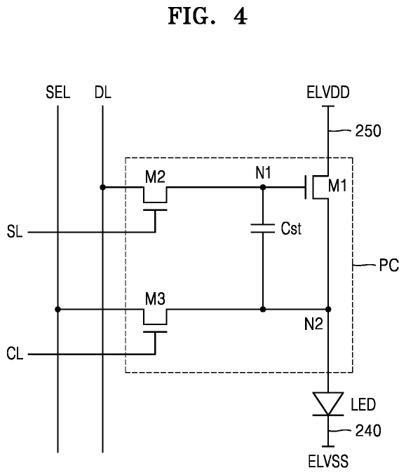

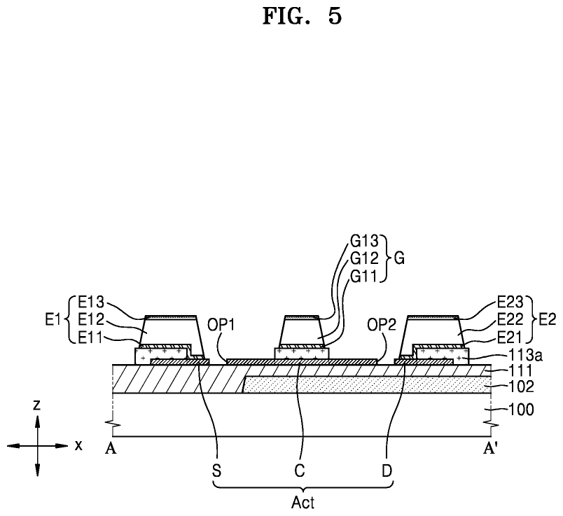

FIG. 4 is a schematic diagram of an equivalent circuit of a light-emitting diode LED included in a display apparatus and a pixel circuit PC electrically connected to the light-emitting diode, according to an embodiment. The pixel circuit PC illustrated in FIG. 4 may correspond to each of the first through third pixel circuits PC1 through PC3 described above with reference to FIG. 2, and the light-emitting diode of FIG. 4 may correspond to each of the first through third light-emitting diodes LED1 through LED3 described above with reference to FIG. 2.

Referring to FIG. 4, the light-emitting diode LED, for example, a pixel electrode (for example, an anode) of the light-emitting diode LED, may be connected to the pixel circuit PC, and an opposite electrode (for example, a cathode) of the light-emitting diode LED may be connected to an auxiliary line 240 configured to provide a common voltage ELVSS. The light-emitting diode LED may emit light by a brightness corresponding to the amount of currents supplied from the pixel circuit PC.

The light-emitting diode LED of FIG. 4 may correspond to each of the first through third light-emitting diodes LED1 through LED3 illustrated in FIG. 2, and the pixel circuit PC of FIG. 4 may correspond to each of the first through third pixel circuits PC1 through PC3 illustrated in FIG. 2.

The pixel circuit PC may be configured to control the amount of currents flowing from a driving voltage ELVDD to a common voltage ELVSS through the light-emitting diode LED, in response to a data signal. The pixel circuit PC may include a first transistor M1, a second transistor M2, a third transistor M3, and a storage capacitor Cst.

Each of the first through third transistors M1 through M3 may include an oxide semiconductor transistor including a semiconductor layer including an oxide semiconductor or a silicon semiconductor transistor including a semiconductor layer including polysilicon. According to a type of the transistor, a first electrode of the transistor may be one of a source electrode and a drain electrode, and a second electrode of the transistor may be the other of the source electrode and the drain electrode.

Any one electrode of the first transistor M1 may be connected to a driving voltage line 250 configured to supply the driving voltage ELVDD, and another electrode of the first transistor M1 may be connected to the pixel electrode of the light-emitting diode LED. A gate electrode of the first transistor M1 may be connected to a first node N1. The first transistor M1 may be configured to control the amount of currents flowing through the light-emitting diode LED from the driving voltage ELVDD, in response to a voltage of the first node N1.

The second transistor M2 may include a switching transistor. Any one electrode of the second transistor M2 may be connected to a data line DL, and another electrode of the second transistor M2 may be connected to the first node N1. A gate electrode of the second transistor M2 may be connected to a scan line SL. In case that a scan signal is provided to the second transistor M2 through the scan line SL, the second transistor M2 may be turned on and may electrically connect the data line DL with the first node N1.

The third transistor M3 may include an initialization transistor and/or a sensing transistor. Any one electrode of the third transistor M3 may be connected to a second node N2, and another electrode of the third transistor M3 may be connected to a sensing line SEL. A gate electrode of the third transistor M3 may be connected to a control line CL.

The storage capacitor Cst may be connected between the first node N1 and the second node N2. For example, a first capacitor electrode of the storage capacitor Cst may be connected to the gate electrode of the first transistor M1, and a second capacitor electrode of the storage capacitor Cst may be connected to the pixel electrode of the light-emitting diode LED.

FIG. 4 illustrates the first transistor M1, the second transistor M2, and the third transistor M3 as n-type metal oxide semiconductor (NMOS) transistors, but the disclosure is not limited thereto. For example, at least one of the first transistor M1, the second transistor M2, and the third transistor M3 may be provided as a p-type metal oxide semiconductor (PMOS) transistor.

FIG. 4 illustrates three transistors, but the disclosure is not limited thereto. The pixel circuit PC may include four or more transistors.

At least one of the driving transistor M1, the switching transistor M2, and the sensing transistor M3 may be manufactured by a process described below.

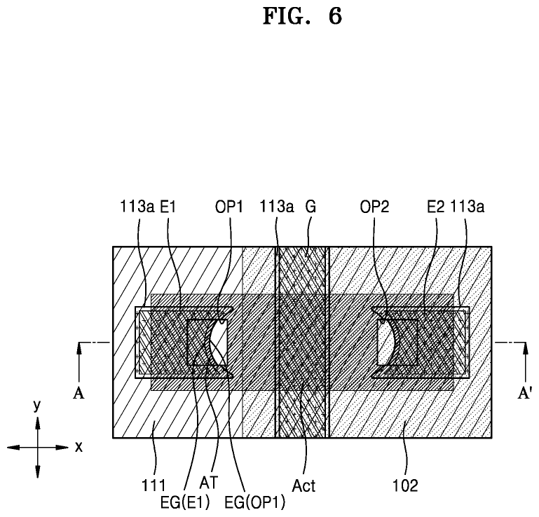

FIG. 5 is a schematic cross-sectional view of the display apparatus DV according to an embodiment. In detail, FIG. 5 is a schematic cross-sectional view of the display apparatus DV taken along line A-A′ of FIG. 6, according to an embodiment.

Referring to FIG. 5, a lower electrode 102 may be arranged on the substrate 100. A buffer layer 111 may be arranged on the lower electrode 102. FIG. 5 illustrates one lower electrode 102, but the disclosure is not limited thereto. There may be two or more lower electrodes 102.

The substrate 100 may include glass materials or polymer resins. In case that the substrate 100 includes polymer resins, the substrate 100 may include polymer resins, such as polyethersulfone, polyarylate, polyetherimide, polyethylene naphthalate, polyethylene terephthalate, polyphenylene sulfide, polyimide, polycarbonate, cellulose tri acetate, and/or cellulose acetate propionate.

Although not shown, the substrate 100 may include a first base layer, a first barrier layer, a second base layer, and a second barrier layer. According to an embodiment, the first base layer, the first barrier layer, the second base layer, and the second barrier layer may be stacked on each other in a thickness direction of the substrate 100.

The first barrier layer and the second barrier layer may prevent the penetration of external impurities and may include a single layer or layers including an inorganic material, such as silicon nitride (SiNₓ), silicon oxide (SiO₂), and/or silicon oxynitride (SiON).

The lower electrode 102 may include a conductive material including Mo, Al, Cu, Ti, etc. and may include a layer or layers including the conductive material described above.

The buffer layer 111 configured to prevent the penetration of impurities into a semiconductor layer Act of a thin-film transistor (TFT) may be formed on the substrate 100. The buffer layer 111 may include an inorganic insulating material, such as silicon nitride, silicon oxynitride, and/or silicon oxide, and may include a single layer or layers including the inorganic insulating material described above.

The semiconductor layer Act may be arranged on the buffer layer 111. The semiconductor layer Act may include an oxide semiconductor. The oxide semiconductor may include indium gallium zinc oxide (IGZO), zinc tin oxide (ZTO), zinc indium oxide (ZIO), etc. However, the disclosure is not limited thereto.

The semiconductor layer Act may be formed by patterning a material (not shown) for forming a semiconductor layer. FIG. 5 illustrates the semiconductor layer Act including the oxide semiconductor. However, according to some embodiments, the material for forming the semiconductor layer may include amorphous silicon or polysilicon. Hereinafter, the disclosure is described based on the assumption that the semiconductor layer Act includes the oxide semiconductor, according to an embodiment. The material for forming the semiconductor layer may be deposited by a chemical vapor deposition (CVD) method.

According to an embodiment, the semiconductor layer Act may include a first opening portion OP1 and a second opening portion OP2. The first opening portion OP1 and the second opening portion OP2 of the semiconductor layer Act may be formed by etching at least a portion of the semiconductor layer Act, in case that the first electrode E1, the gate electrode G, and the second electrode E2 are formed by etching a material for forming an electrode. In other words, the first opening portion OP1 and the second opening portion OP2 of the semiconductor layer Act may be simultaneously formed with the first electrode E1, the gate electrode G, and the second electrode E2, in case that the first electrode E1, the gate electrode G, and the second electrode E2 are formed. This aspect will be described in more detail below.

An insulating pattern layer 113a may be formed on the semiconductor layer Act. The insulating pattern layer 113a may be arranged to partially surround the first electrode E1 and the second electrode E2. The insulating pattern layer 113a may be formed by etching an inorganic insulating layer 113 arranged between the semiconductor layer Act and the first electrode E1, the second electrode E2, and the gate electrode G. Because the insulating pattern layer 113a may be formed by etching the inorganic insulating layer 113, at least a portion of the semiconductor layer Act arranged below the gate electrode G may be exposed. The portion of the semiconductor layer Act, exposed by the insulating pattern layer 113a, may become conductive via plasma processing, etc. The portion of the semiconductor layer Act, arranged below the gate electrode G and exposed by the insulating pattern layer 113a, may become conductive, and thus, a conductive channel area C of the semiconductor layer Act may be formed.

According to an embodiment, at least a portion of the semiconductor layer Act arranged below the first electrode E1 and at least a portion of the semiconductor layer Act arranged below the second electrode E2, the portions being exposed by the insulating pattern layer 113a, may become conductive via plasma processing, before the first electrode E1 and the second electrode E2 are arranged thereabove. The portion of the semiconductor layer Act arranged below the first electrode E1, the portion being exposed by the insulating pattern layer 113a, may become conductive, and thus, a source area S of the semiconductor layer Act may be formed, and the portion of the semiconductor layer Act arranged below the second electrode E2, the portion being exposed by the insulating pattern layer 113a, may become conductive, and thus, a drain area D of the semiconductor layer Act may be formed.

According to an embodiment, the first electrode E1 may overlap and may be electrically connected to the source area S or the drain area D of the semiconductor layer Act. The second electrode E2 may overlap and may be electrically connected to the source area S or the drain area D of the semiconductor layer Act. However, the disclosure is not limited thereto.

According to an embodiment, the insulating pattern layer 113a may include SiO₂, SiNₓ, SiON, Al₂O₃, TiO₂, TA₂O₅, HfO₂, ZnO₂, etc. and may be formed by using deposition, such as CVD, sputtering, etc. However, the insulating pattern layer 113a is not limited thereto.

According to an embodiment, the first electrode E1, the second electrode E2, and the gate electrode G may be arranged above the insulating pattern layer 113a. The first electrode E1, the second electrode E2, and the gate electrode G may be formed by forming the material for forming the electrode on the substrate 100 and patterning the material for forming the electrode. This aspect will be described in more detail below.

The material for forming the electrode may include a single conductive layer or conductive layers. According to an embodiment, the material for forming the electrode may include a material for forming a first sub-electrode, a material for forming a second sub-electrode, and a material for forming a third sub-electrode, wherein the materials for forming the first, second, and third sub-electrodes include different metals from one another, and the material for forming the third sub-electrode is arranged on the material for forming the second sub-electrode. According to an embodiment, the material for forming the first sub-electrode and the material for forming the second sub-electrode layer may include a conductive material including Al, Pt, Pd, Ag, Mg, Au, Ni, Nd, Ir, Cr, Li, Ca, Mo, Ti, W, and/or Cu. The material for forming the third sub-electrode layer may include a transparent conductive material. The transparent conductive material may include a conductive oxide, such as ITO, IZO, ZnO, In₂O₃, IGO, and/or AZO.

Hereinafter, the disclosure is described based on a case in which the material for forming the electrode includes the materials for forming the three sub-electrodes. The first electrode E1, the second electrode E2, and the gate electrode G formed by patterning the material for forming the electrode may include first to third sub-electrodes E11 to E13, first to third sub-electrodes E21 to E23, and first to third sub-electrodes G11 to G13, respectively, as illustrated in FIG. 5. The second sub-electrodes E12, E22, and G12 may be arranged on the first sub-electrodes E11, E21, and G11, respectively, and the third sub-electrodes E13, E23, and G13 may be arranged on the second sub-electrodes E12, E22, and G12, respectively. In other words, each of the first to third sub-electrodes E11 to E13, E21 to E23, and G11 to G13 may be stacked on each other. According to an embodiment, each of the first sub-electrodes E11, E21, and G11 may include Ti, each of the second sub-electrodes E12, E22, and G12 may include Cu, and each of the third sub-electrodes E13, E23, and G13 may include ITO. The first to third sub-electrodes E11 to E13, the first to third sub-electrodes E21 to E23, and the first to third sub-electrodes G11 to G13 included in the first electrode E1, the second electrode E2, and the gate electrode G, respectively, may correspond to portions formed by patterning the material for forming the first sub-electrode, the material for forming the second sub-electrode, and the material for forming the third sub-electrode, included in the material for forming the electrode.

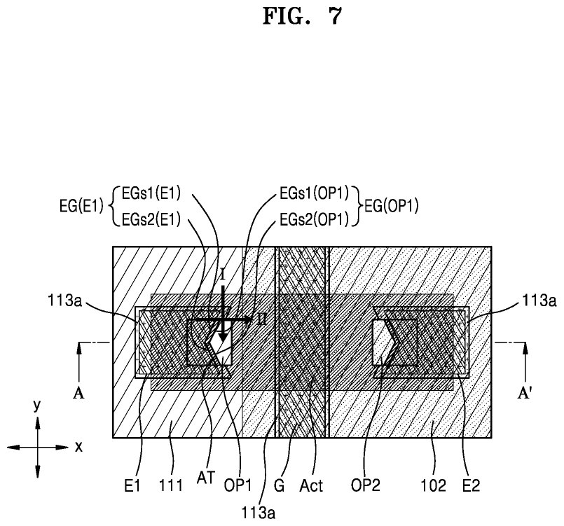

FIGS. 6 and 7 are schematic plan views of the display apparatus DV according to embodiments. In detail, FIGS. 6 and 7 are downward-looking schematic plan views of the display apparatus DV of FIG. 5, according to embodiments.

Referring to FIGS. 6 and 7, on an x-y plane, the first electrode E1 may have an edge (or a boundary) EG (E1) adjacent to the first opening portion OP1 of the semiconductor layer Act. The edge EG (E1) of the first electrode E1, the edge EG (E1) being adjacent to the first opening portion OP1, may be formed to be concave in a direction toward the conductive semiconductor layer Act arranged below the first electrode E1. In other words, the edge EG (E1) of the first electrode E1, adjacent to the first opening portion OP1, may be formed to be concave in a direction toward the source area S (or the drain area D, see FIG. 5) of the semiconductor layer Act arranged below the first electrode E1. The first opening portion OP1 adjacent to the first electrode E1 may also have an edge EG (OP1). The edge EG (OP1) of the first opening portion OP1 may be formed to be protrusive in a direction toward the conductive semiconductor layer Act arranged below the first electrode E1. The edge EG (OP1) of the first opening portion OP1 may also be formed to be protrusive in a direction toward the source area S (or the drain area D) of the semiconductor layer Act arranged below the first electrode E1. An edge of the second electrode E2 and an edge of the second opening portion OP2 may be formed to correspond to the edge EG (E1) of the first electrode E1 and the edge EG (OP1) of the first opening portion OP1, respectively. However, the disclosure is not limited thereto.

According to an embodiment, as illustrated in FIG. 6, the edge EG (E1) of the first electrode E1 may have an arc shape. The edge EG (E1) of the first electrode E1 may be formed to have the arc shape and to be concave in the direction toward the source area S (or the drain area D) of the semiconductor layer Act arranged below the first electrode E1. The edge EG (OP1) of the first opening portion OP1 may also have an arc shape. The edge EG (OP1) of the first opening portion OP1 may be formed to have the arc shape and to be protrusive in the direction toward the source area S (or the drain area D) of the semiconductor layer Act arranged below the first electrode E1. The edge of the second electrode E2 and the edge of the second opening portion OP2 may be formed to correspond to the edge EG (E1) of the first electrode E1 and the edge EG (OP1) of the first opening portion OP1, respectively.

According to an embodiment, as illustrated in FIG. 7, the edge EG (E1) of the first electrode E1 may include a first sub-edge EGs1 (E1) of the first electrode E1 and a second sub-edge EGs2 (E1) of the first electrode E1. The first sub-edge EGs1 (E1) of the first electrode may extend in a first direction, and the second sub-edge EGs2 (E1) of the first electrode E1 may extend in a second direction. In other words, the first sub-edge EGs1 (E1) of the first electrode E1 may have a shape of a straight line extending in the first direction, and the second sub-edge EGs2 (E1) of the first electrode E1 may have a shape of a straight line extending in the second direction. The first sub-edge EGs1 (E1) of the first electrode E1 and the second sub-edge EGs2 (E1) of the first electrode E1 may be formed to be concave in a direction toward the source area S (or the drain area D) of the semiconductor layer Act arranged below the first electrode E1. The first sub-edge EGs1 (E1) of the first electrode E1 and the second sub-edge EGs2 (E1) of the first electrode E1 may cross (intersect) each other. The edge EG (OP1) of the first opening portion OP1 may include a first sub-edge EGs1 (OP1) of the first opening portion OP1 and a second sub-edge EGs2 (OP1) of the first opening portion OP1. The first sub-edge EGs1 (OP1) of the first opening portion OP1 may extend in a first direction, and the second sub-edge EGs2 (OP1) of the first opening portion OP1 may extend in a second direction. In other words, the first sub-edge EGs1 (OP1) of the first opening portion OP1 may have a shape of a straight line extending in the first direction, and the second sub-edge EGs2 (OP1) of the first opening portion OP1 may have a shape of a straight line extending in the second direction. The first sub-edge EGs1 (OP1) of the first opening portion OP1 and the second sub-edge EGs2 (OP1) of the first opening portion OP1 may be formed to be protrusive in the direction toward the source area S (or the drain area D) of the semiconductor layer Act arranged below the first electrode E1. The first sub-edge EGs1 (OP1) of the first opening portion OP1 and the second sub-edge EGs2 (OP1) of the first opening portion OP1 may cross each other. The edge of the second electrode E2 and the edge of the second opening portion OP2 may be formed to correspond to the edge of the first electrode E1 and the edge of the first opening portion OP1, respectively.

According to an embodiment, a portion AT of the semiconductor layer Act may be arranged between the edge EG (E1) of the first electrode E1 and the first opening portion OP1. The portion AT of the semiconductor layer Act may correspond to the source area S (or the drain area D), which is a conductive portion of the semiconductor layer Act. In other words, the portion AT of the semiconductor layer Act may correspond to a portion of the conductive semiconductor layer Act, the portion not being etched and remaining. Currents may flow from the portion AT of the semiconductor layer Act to the semiconductor layer Act adjacent to the first opening portion OP1 along a side of the first opening portion OP1 extending in an x direction. The semiconductor layer Act may be arranged below the insulating pattern layer 113a adjacent to the side of the first opening OP1 extending in the x direction. At least a portion of the semiconductor layer Act, arranged below the insulating pattern layer 113a adjacent to the side of the first opening portion OP1 extending in the x direction, may become simultaneously conductive, in case that the semiconductor layer Act exposed by the insulating pattern layer 113a becomes conductive via plasma processing. In other words, in case that the channel area C of the semiconductor layer Act is formed, the portion of the semiconductor layer Act, arranged below the insulating pattern layer 113a adjacent to the side of the first opening portion OP1 extending in the x direction, may become conductive at the same time. Because the portion of the semiconductor layer Act, arranged below the insulating pattern layer 113a adjacent to the side of the first opening portion OP1 extending in the x direction, may become conductive, currents may flow from the portion AT of the semiconductor layer Act to the channel area C of the semiconductor layer Act adjacent to the first opening portion OP1, along the side of the first opening portion OP1 extending in the x direction.

Unlike the embodiments illustrated in FIGS. 6 and 7, the edge of the first electrode E1 according to the related art may be formed to extend in a y direction. In other words, according to the related art, the edge of the first electrode E1 may have a shape of a straight line extending in the y direction. In case that the first opening portion OP1 is formed by forming the first electrode E1 by patterning the material for forming the electrode and, at the same time, etching at least a portion of the semiconductor layer Act, a wet etching process may be used. Wet etching may allow further etching according to a degree of a developer (for example, an etchant) contained in an etching process. In other words, in case that the first opening OP1 of the semiconductor layer Act is formed by etching the first electrode E1 and the semiconductor layer Act, an error may occur in the etching process. Due to the error in the etching process, the first opening portion OP1 may be formed to have an increased size, and the portion AT of the semiconductor layer Act may be formed to have a decreased thickness. A side of the insulating pattern layer 113a contacting the first opening portion OP1 may have an increased length. In case that the first opening portion OP1 has an increased size, the semiconductor layer Act arranged below the insulating pattern layer 113a adjacent to the first opening portion OP1 may become relatively less conductive, and thus, the flow of currents to the portion AT of the semiconductor layer Act, the side of the first opening portion OP1 extending in the x direction, and the channel area C of the semiconductor layer Act may be interrupted. In other words, in case that the first opening portion OP1 is formed to have an increased size due to the error in a wet etching process, the flow of the currents to the portion AT of the semiconductor layer Act, the semiconductor layer Act arranged below the insulating pattern layer 113a adjacent to the first opening portion OP1, and the channel area C of the semiconductor layer Act may be interrupted.

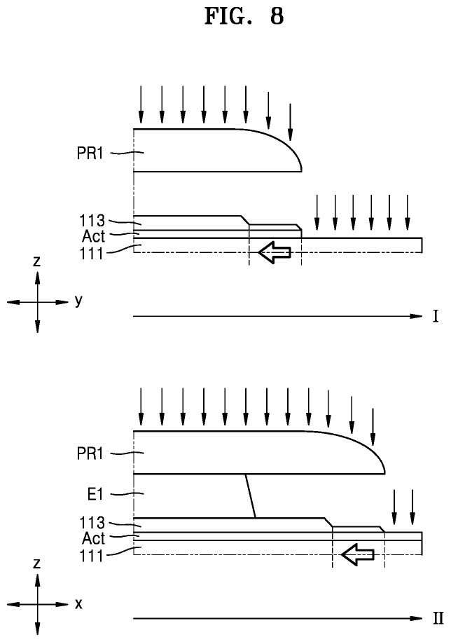

FIG. 8 shows schematic cross-sectional views of the display apparatus DV of FIG. 7, according to an embodiment. In detail, FIG. 8 shows schematic cross-sectional views of the display apparatus DV of FIG. 7, viewed in directions I and II, according to an embodiment.

FIG. 8 illustrates that a first photoresist PR1 is arranged in the display apparatus DV of FIG. 7. FIG. 8 shows schematic cross-sectional views for describing an operation included in a process of forming the display apparatus DV. In detail, after arranging the first photoresist PR1, a second photoresist PR2, and a third photoresist PR3 on the material for forming the electrode, the material for forming the electrode may be etched and at least a portion of the semiconductor layer Act arranged below the material for forming the electrode may be etched, to form the first electrode E1, the gate electrode G, and the first opening portion OP1 of the semiconductor layer Act. Thereafter, a portion of the inorganic insulating layer 113 may be etched to form the insulating pattern layer 113a. Here, a process of making conductive at least a portion of the semiconductor layer Act, the portion being exposed by the insulating pattern layer 113a and arranged below the gate electrode G, is illustrated. In detail, it is illustrated that, in the process of making conductive the portion of the semiconductor layer Act, arranged below the gate electrode G, at least a portion of the semiconductor layer Act, arranged below the insulating pattern layer 113a adjacent to the first opening portion OP1, is also made conductive.

Referring to the cross-sectional view of FIG. 8 showing the display apparatus DV viewed in direction I, the first electrode E1 may be formed to be concave in a direction from the first opening portion OP1 toward the source area S or the drain area D of the semiconductor layer Act, and thus, the first photoresist PR1 may be disconnected in the cross-sectional view of the display apparatus in direction I. Because the first photoresist PR1 is disconnected, a portion of the semiconductor layer Act arranged below the insulating pattern layer 113a may additionally become conductive. Referring to the cross-sectional view of FIG. 8 showing the display apparatus DV in direction II, the first electrode E1 may be formed to be concave in a direction from the first opening portion OP1 toward the source area S or the drain area D, and thus, the first photoresist PR1 may be formed to be inclined in the cross-sectional view of the display apparatus in direction II. Because the first photoresist PR1 slopes, at least a portion of the semiconductor layer Act arranged below the insulating pattern layer 113a may additionally become conductive. In conclusion, because the first electrode E1 may be formed to be concave in the direction from the first opening portion OP1 toward the source area S or the drain area D of the semiconductor layer Act, the flow of currents to the portion AT of the semiconductor layer Act, the side of the first opening portion OP1 in the x direction, and the semiconductor layer Act adjacent to the first opening portion OP1 may be improved.

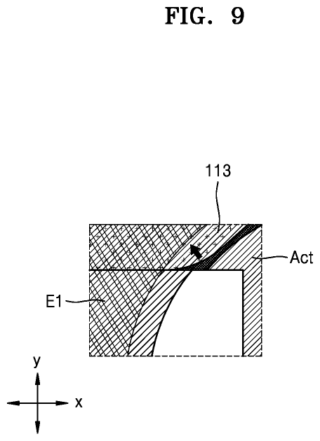

FIG. 9 is a schematic cross-sectional view of an enlarged portion of the first opening portion OP1 of FIG. 7.

Referring to FIG. 9, as illustrated in FIG. 8, because the first electrode E1 may be formed to be concave in the direction from the first opening portion OP1 toward the source area S or the drain area D of the semiconductor layer Act, the portion of the semiconductor layer Act arranged below the insulating pattern layer 113a adjacent to the first opening OP1 may additionally become conductive. To see this in a plan view of the display apparatus DV, as illustrated in FIG. 9, an area of the conductive portion of the semiconductor layer Act arranged below the insulating pattern layer 113a adjacent to the first opening portion OP1 may be increased. Because the conductive portion of the semiconductor layer Act arranged below the insulating pattern layer 113a adjacent to the first opening portion OP1 has the increased area, a degree of the flow of currents to the portion AT of the semiconductor layer Act, the side of the first opening portion OP1 in the x direction, and the semiconductor layer Act adjacent to the first opening portion OP1 may be improved. In other words, in case that the conductive portion of the semiconductor layer Act arranged below the insulating pattern layer 113a adjacent to the first opening portion OP1 has the increased area, a degree of the flow of currents to the portion AT of the semiconductor layer Act, the semiconductor layer Act arranged below the insulating pattern layer 113a adjacent to the first opening portion OP1, and the semiconductor layer Act adjacent to the first opening portion OP1 may be improved.

According to an embodiment, in case that the first electrode E1 is formed to be concave in the direction from the first opening portion OP1 toward the source area S or the drain area D of the semiconductor layer Act, side effects which may occur due to an error occurring in a wet etching process may be prevented. As described above, in case that the conductive portion of the semiconductor Act arranged below the insulating pattern layer 113a adjacent to the first opening portion OP1 has the increased area, interruption of the flow of currents, which may occur in case that the area of the first opening portion OP1 is increased in the wet-etching process, may be compensated for. In case that the first electrode E1 is formed to be concave in the direction from the first opening portion OP1 toward the source area S or the drain area D of the semiconductor layer Act, side effects which may occur due to an overlay shift between layers, which may occur in the overlay structure of the display apparatus DV, may be prevented. In case that the first electrode E1 is formed to be concave in the direction from the first opening portion OP1 toward the source area S or the drain area D of the semiconductor layer Act, a length in the x direction of a portion at which the first opening portion OP1 and the insulating pattern layer 113a contact each other, may be maintained to be the same, even in case that an error occurs in an overlay process of layers.

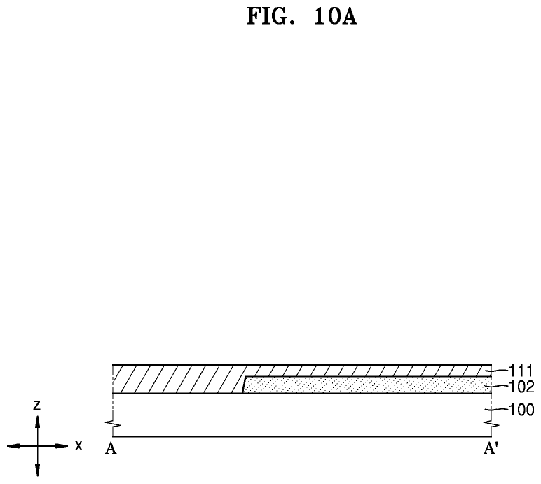

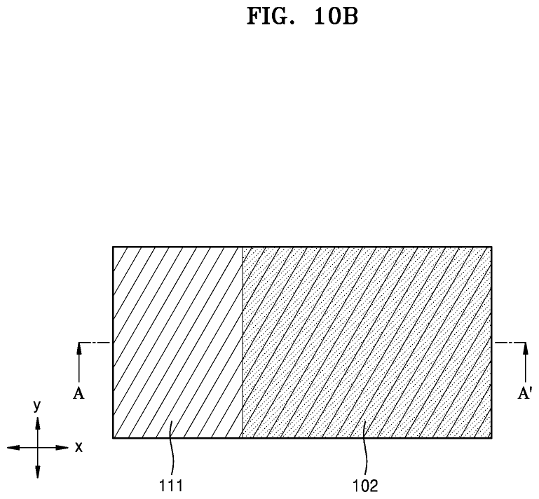

FIGS. 10A, 11A, 12A, 13A, 14A, and 15A are schematic cross-sectional views for describing a method of manufacturing the display apparatus DV, according to embodiments. FIGS. 10B, 11B, 12B, 13B and 13C, 14B and 14C, and 15B and 15C are plan views of the downwardly viewed display apparatus of FIGS. 10A, 11A, 12A, 13A, 14A, and 15A, respectively, according to embodiments.

The method of manufacturing the display apparatus DV may include forming, on the substrate 100, the semiconductor layer Act including the channel area C and the source area S and the drain area D at both sides of the channel area C, forming the material for forming the electrode on the semiconductor layer Act, forming the first photoresist PR1 on the material for forming the electrode, and forming the first electrode E1 by etching the material for forming the electrode. In case that the material for forming the electrode is etched, at least a portion of the semiconductor layer Act may be etched, and thus, the first opening portion OP1 may be formed at a location adjacent to any one of the source area S and the drain area D. The edge EG (E1) of the first electrode E1 may be formed to be concave in a direction from the first opening portion OP1 toward the source area S or the drain area D. The method of manufacturing the display apparatus DV may further include forming the insulating pattern layer 113a by etching the inorganic insulating layer 113 arranged between the semiconductor layer Act and the gate electrode G. This aspect will be described in more detail below.

Referring to FIGS. 10A and 10B, the lower electrode 102 may be formed on the substrate 100. The buffer layer 111 may be formed on the lower electrode 102.

According to an embodiment, the lower electrode 102 may have a multi-layered structure. For example, the lower electrode 102 may have a Ti/Cu/ITO multi-layered structure. Here, in order to prevent a tip of upper ITO, an etching process using different etchants may be performed twice or more, and each lower electrode 102 may have a side surface tapered in a normal direction as illustrated in FIG. 5. According to another embodiment, an etching process may be performed only once by using an etchant for etching all of Ti, Cu, and ITO.

The lower electrode 102 may be formed by patterning a material (not shown) for forming a conductive layer. The material for forming the conductive layer may include a conductive material including Mo, Al, Cu, Ti, and/or the like and may include layers or a single layer including the material described above.

The buffer layer 111 may include an inorganic insulating material, such as SiNₓ, SiON, and SiO₂, and may include a single layer or layers including the inorganic insulating material described above. The buffer layer 111 may be formed by using a deposition method, such as CVD, sputtering, etc.

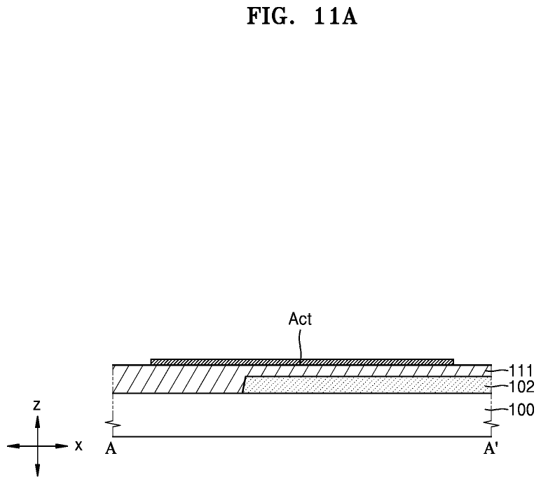

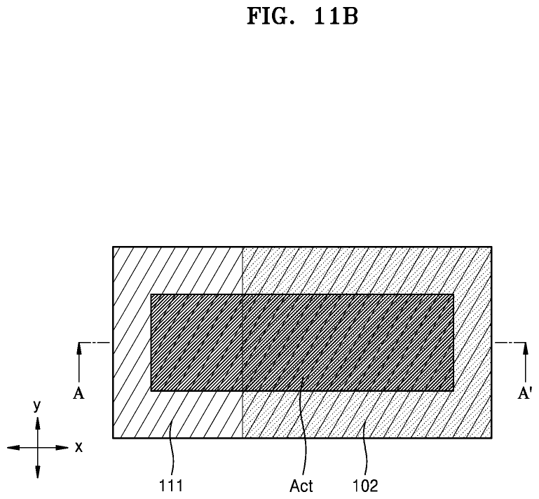

Referring to FIGS. 11A and 11B, the semiconductor layer Act may be formed on the buffer layer 111. The forming of the semiconductor layer Act including the source area S and the drain area D may include forming a material for forming a semiconductor layer on the substrate 100 and forming the semiconductor layer Act by patterning the material for forming the semiconductor layer.

The material for forming the semiconductor layer may include an oxide semiconductor. The oxide semiconductor may include indium gallium zinc oxide (IGZO), zinc tin oxide (ZTO), zinc indium oxide (ZIO), etc. However, the disclosure is not limited thereto. The material for forming the semiconductor layer may be deposited by CVD.

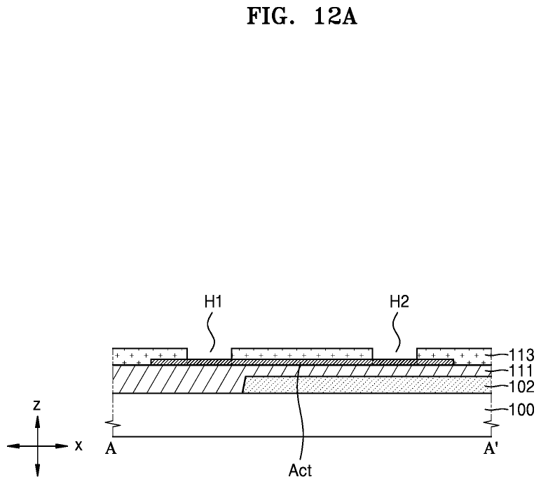

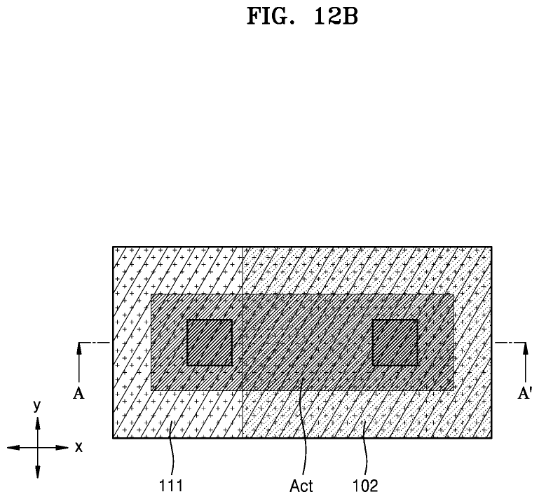

Referring to FIGS. 12A and 12B, the inorganic insulating layer 113 may be formed on the semiconductor layer Act. The inorganic insulating layer 113 may include SiO₂, SiNₓ, SiON, Al₂O₃, TiO₂, TA₂O₅, HfO₂, ZnO₂, etc. and may be formed by using a deposition method, such as CVD, sputtering, etc. However, the inorganic insulating layer 113 is not limited thereto.

According to an embodiment, multiple holes H1 and H2 may be formed by etching at least a portion of the inorganic insulating layer 113. The holes H1 and H2 may be defined in the inorganic insulating layer 113. At least a portion of the semiconductor layer Act may be exposed by the holes H1 and H2 defined in the inorganic insulating layer 113. In case that the holes H1 and H2 are formed in the inorganic insulating layer 113, the exposed portion of the semiconductor layer Act may be made conductive. In detail, the portion of the semiconductor layer Act exposed by the holes H1 and H2 of the inorganic insulating layer 113 may be made conductive by plasma processing. According to an embodiment, the portion of the semiconductor layer Act exposed by the holes H1 and H2 defined in the inorganic insulating layer 113 may be made conductive to become the source area S or the drain area D of the semiconductor layer Act.

For example, plasma processing may involve changing a surface of a material chemically or materially, as a particle having a higher energy in a plasma state collides with the surface of the material. According to an embodiment, during the plasma processing, at least one gas selected from the group consisting of an argon gas, a helium gas, a xenon gas, a nitrogen gas, a nitrogen oxide gas, an oxygen gas, and a mixture gas thereof may be used.

In case that an oxide semiconductor is processed, the oxide semiconductor may be reduced, and thus, oxygen defects included in the oxide semiconductor may be induced to increase an oxygen vacancy. The oxide semiconductor having an increased oxygen vacancy may have an increased carrier concentration, and thus, a threshold voltage, which may be a critical voltage according to which conductivity, one of the characteristics of the semiconductor, is generated, may have a concentration shifted to a negative direction. This denotes that the oxide semiconductor becomes conductive to be highly electrically conductive.

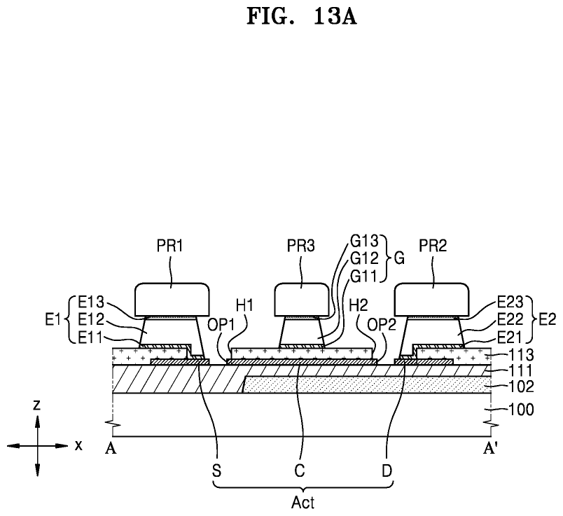

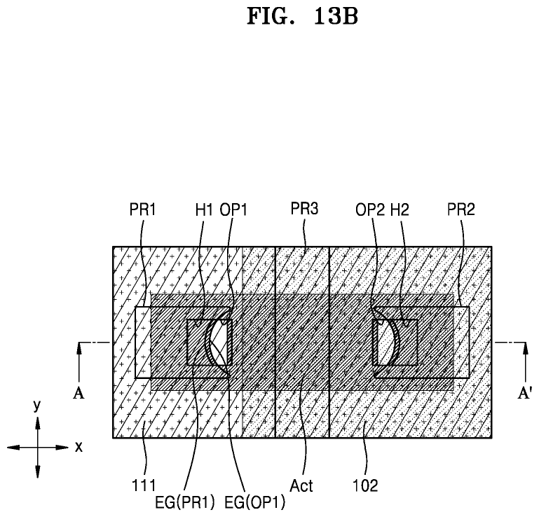

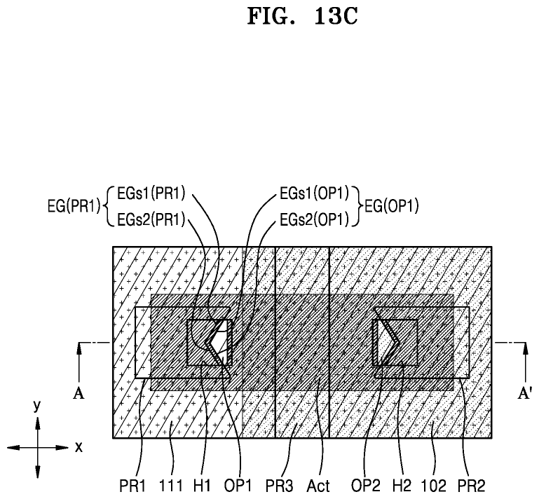

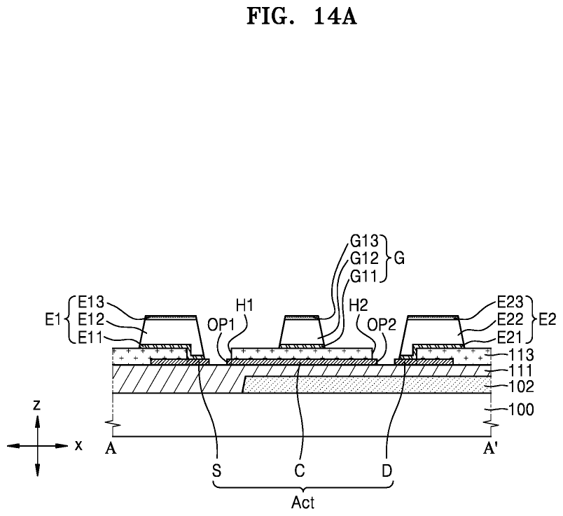

Referring to FIGS. 13A, 13B, and 13C, the material for forming the electrode may be formed on the inorganic insulating layer 113. The first electrode E1, the second electrode E2, and the gate electrode G may be formed by patterning (or etching) the material for forming the electrode. In detail, by arranging the first to third photoresists PR1 to PR3 on the material for forming the electrode and patterning (or etching) the material for forming the electrode, the first electrode E1, the second electrode E2, and the gate electrode G may be formed. The material for forming the electrode may be formed by using a deposition method, such as CVD (plasma enhanced CVD (PECVD), low pressure CVD (LPCVD)), physical vapor deposition (PVD), sputtering, atomic layer deposition (ALD), etc.

The material for forming the electrode may include the material for forming the first sub-electrode, the material for forming the second sub-electrode, and the material for forming the third sub-electrode. For example, the material for forming the first sub-electrode may include Ti, the material for forming the second sub-electrode may include Cu, and the material for forming the third sub-electrode may include ITO. However, the disclosure is not limited thereto.

In case that the material for forming the electrode includes the material for forming the first sub-electrode, the material for forming the second sub-electrode, and the material for forming the third sub-electrode, the first electrode E1, the second electrode E2, and the third electrode E3 may include the first to third sub-electrodes E11 to E13, the first to third sub-electrodes E21 to E23, and the first to third sub-electrodes G11 to G13, respectively. However, the disclosure is not limited thereto. In case that the first electrode E1, the second electrode E2, and the third electrode E3 include the first to third sub-electrodes E11 to E13, the first to third sub-electrodes E21 to E23, and the first to third sub-electrodes G11 to G13, respectively, the third sub-electrodes E13, E23, and G13 may prevent or reduce damage to the second sub-electrodes E12, E22, and G12, respectively, during a manufacturing process of the display apparatus. According to another embodiment, in case that the second sub-electrodes E12, E22, and G12 have chemical resistance, the third sub-electrodes E13, E23, and G13 may be omitted.

The first photoresist PR1, the second photoresist PR2, and the third photoresist PR3 may be arranged on the material for forming the electrode. The first photoresist PR1 may be arranged to correspond to a portion of the material for forming the electrode at which the first electrode E1 is to be formed, the second photoresist PR2 may be arranged to correspond to a portion of the material for forming the electrode at which the second electrode E2 is to be formed, and the third photoresist PR3 may be arranged to correspond to a portion of the material for forming the electrode at which the gate electrode G is to be formed. Portions of the material for forming the electrode, on which the first to third photoresists PR1 to PR3 are not arranged, may be wet-etched. By etching the portions of the material for forming the electrode, on which the first to third photoresists PR1 to PR3 are not arranged, the first electrode E1, the second electrode E2, and the gate electrode G may be formed. In other words, the material for forming the electrode arranged below the first photoresist PR1 may become the first electrode E1, the material for forming the electrode arranged below the second photoresist PR2 may become the second electrode E2, and the material for forming the electrode arranged below the third photoresist PR3 may become the gate electrode G.

According to an embodiment, the first photoresist PR1 may include an edge EG (PR1) adjacent to the first opening portion OP1. The edge EG (PR1) of the first photoresist PR1 may be formed to be concave in a direction from the channel area C of the semiconductor layer Act toward the source area S or the drain area D of the semiconductor layer Act. In other words, the edge EG (PR1) of the first photoresist PR1 may be formed in a direction toward the semiconductor layer Act that is conductive and arranged below the first electrode E1. An edge of the second photoresist PR2 may be formed to correspond to the edge of the first photoresist PR1.

As illustrated in FIG. 13B, the edge EG (PR1) of the first photoresist PR1 may have an arc shape. The edge EG (PR1) of the first photoresist PR1 may have the arc shape and may be concave in a direction toward the source area S (or the drain area D) of the semiconductor layer Act arranged below the first electrode E1. The edge of the second photoresist PR2 may be formed to correspond to the edge of the first photoresist PR1.

As illustrated in FIG. 13C, the edge EG (PR1) of the first photoresist PR1 may include a first sub-edge EGs1 (PR1) of the first photoresist PR1 and a second sub-edge EGs2 (PR1) of the first photoresist PR1. The first sub-edge EGs1 (PR1) of the first photoresist PR1 may extend in a first direction, and the second sub-edge EGs2 (PR1) of the first photoresist PR1 may extend in a second direction. In other words, the first sub-edge EGs1 (PR1) of the first photoresist PR1 may have a shape of a straight line extending in the first direction, and the second sub-edge EGs2 (PR1) of the first photoresist PR1 may have a shape of a straight line extending in the second direction. The first sub-edge EGs1 (PR1) and the second sub-edge EGs2 (PR1) of the first photoresist PR1 may be formed to be concave in a direction toward the source area S (or the drain area D) of the semiconductor layer Act arranged below the first electrode E1. The first sub-edge EGs1 (PR1) of the first photoresist PR1 and the second sub-edge EGs2 (PR1) of the first photoresist PR1 may cross each other. The edge of the second photoresist PR2 may be formed to correspond to the edge of the first photoresist PR1.

After the first electrode E1, the second electrode E2, and the gate electrode G are formed by wet-etching the material for forming the electrode, the portion of the semiconductor layer Act, exposed to the outside, because the inorganic insulating layer 113 is not arranged thereabove, may be etched together. In other words, in case that the first electrode E1, the second electrode E2, and the gate electrode G are formed by etching the material for forming the electrode, the portion of the semiconductor layer Act exposed to the outside may be etched at the same time. Some etched portions of the semiconductor layer Act may be included in the portion of the semiconductor layer Act, exposed by the inorganic insulating layer 113 and made conductive in the previous process.

In case that the material for forming the electrode is etched, at least a portion of the semiconductor layer Act may be etched, and thus, openings (for example, the first opening portion OP1 and the second opening portion OP2) may be defined at locations adjacent to any one of the source area S and the drain area D. The openings of the semiconductor layer Act may include the first opening portion OP1 and the second opening portion OP2. The first and second opening portions OP1 and OP2 may be arranged at both sides of the channel area C with the channel area C therebetween. While the first opening portion OP1 of the semiconductor layer Act may be arranged between the channel area C and the first electrode E1, the first opening portion OP1 may be arranged to be adjacent to the first electrode E1, and while the second opening portion OP2 of the semiconductor layer Act may be arranged between the channel area C and the second electrode E2, the second opening portion OP2 may be arranged to be adjacent to the second electrode E2. The opening portions OP1 and OP2 may be formed to penetrate an upper surface and a lower surface of the semiconductor layer Act, and thus, the buffer layer 111 may be exposed by the opening portions OP1 and OP2.

The conductive portion of the semiconductor layer Act, which is not etched, may overlap the first electrode E1 and the second electrode E2. The portion AT of the semiconductor layer, the portion AT not overlapping the first electrode E1 and the second electrode E2, may be connected to the channel area C of the conductive semiconductor layer Act, in a sequential process.

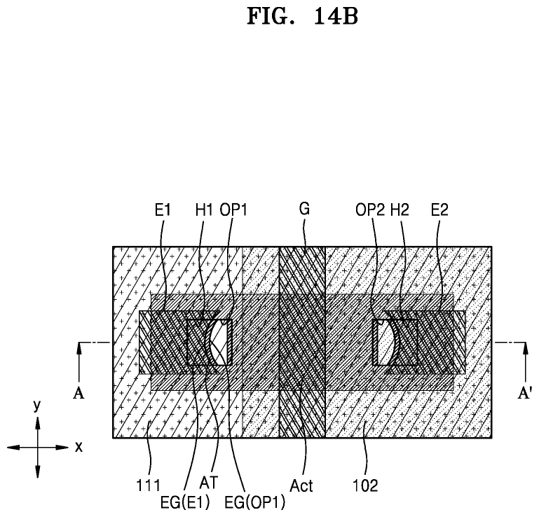

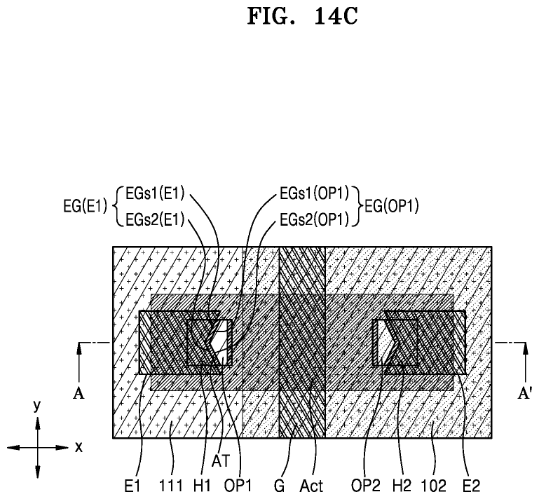

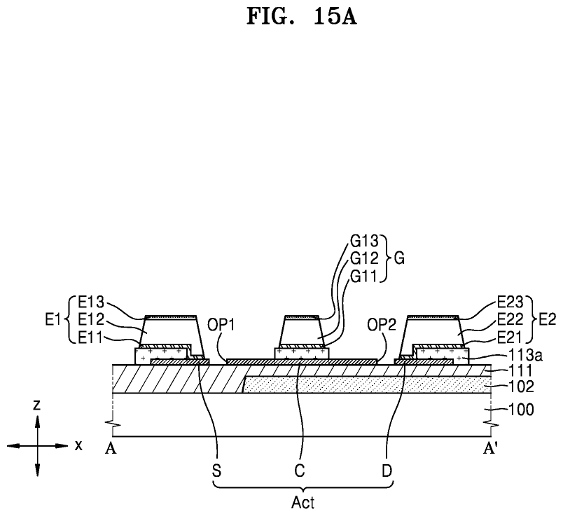

Referring to FIGS. 14A, 14B, and 14C, the first to third photoresists PR1 to PR3 arranged on the substrate 100 may be removed. The material for forming the electrode arranged below the first to third photoresists PR1 to PR3 may not be etched and may remain, and thus, the shape of the first electrode E1, the second electrode E2, and the gate electrode G may be determined by the shape of the first to third photoresists PR1 to PR3.

According to an embodiment, the shape of the first photoresist PR1 may be concave in the direction from the channel area C of the semiconductor layer Act toward the source area S of the semiconductor layer Act, as described above. The first electrode E1 may have the edge EG (E1) adjacent to the first opening portion OP1. The edge EG (E1) of the first electrode E1 may be formed to be concave in a direction from the first opening portion OP1 toward the source area S or the drain area D of the semiconductor layer Act. The edge EG (E1) of the first electrode E1 may have an arc shape as illustrated in FIG. 14B. The edge EG (E1) of the first electrode E1 may have the arc shape and may be formed to be concave in the direction toward the source area S or the drain area D.

According to an embodiment, the edge EG (E1) of the first electrode may include the first sub-edge EGs1 (E1) of the first electrode E1 and the second sub-edge EGs2 (E1) of the first electrode E1, as illustrated in FIG. 14C. The first sub-edge EGs1 (E1) of the first electrode may extend in a first direction, and the second sub-edge EGs2 (E1) of the first electrode E1 may extend in a second direction. In detail, the first sub-edge EGs1 (E1) of the first electrode E1 may have a shape of a straight line extending in the first direction, and the second sub-edge EGs2 (E1) of the first electrode E1 may have a shape of a straight line extending in the second direction. The first sub-edge EGs1 (E1) of the first electrode E1 and the second sub-edge EGs2 (E1) of the first electrode E1 may be formed to be concave in the direction toward the source area S or the drain area D of the semiconductor layer Act. The first sub-edge EGs1 (E1) of the first electrode E1 and the second sub-edge EGs2 (E1) of the first electrode E1 may cross each other.

In case that the first photoresist PR1 is removed, the portion AT of the conductive semiconductor layer Act may be arranged between the first opening portion OP1 and the first electrode E1, when the display apparatus DV is viewed in a plan view. The portion AT of the semiconductor layer CT may be the portion that is made conductive in the previous process and may correspond to a portion not etched and remaining, in case that the portion of the semiconductor layer Act is etched.

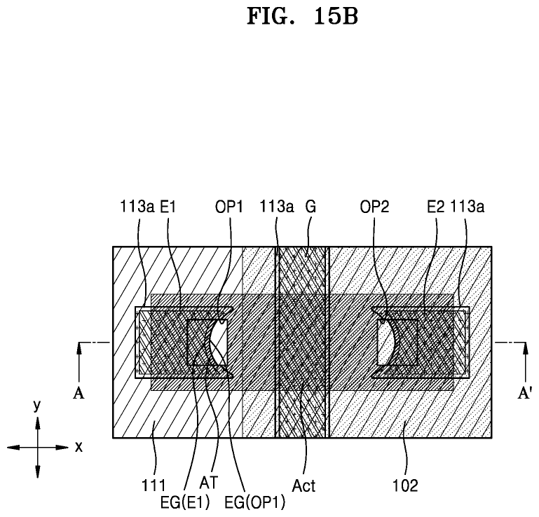

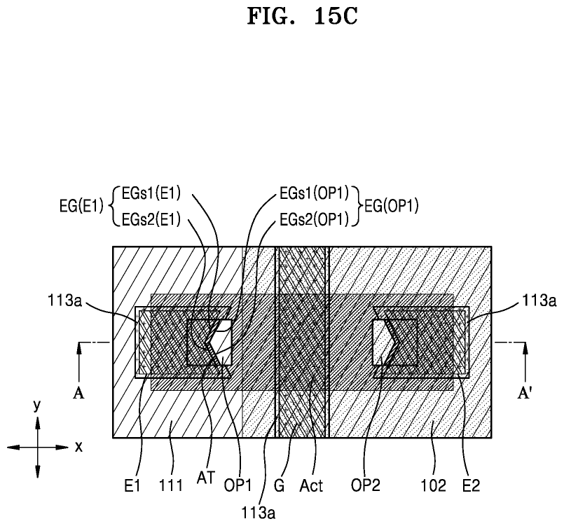

Referring to FIGS. 15A, 15B, and 15C, the insulating pattern layer 113a may be formed by etching at least a portion of the inorganic insulating layer 113 arranged between the semiconductor layer Act and the first electrode E1. The inorganic insulating layer 113 may be arranged between the semiconductor layer Act and the first electrode E1, the second electrode E2, and the gate electrode G.

According to an embodiment, by etching at least a portion of the inorganic insulating layer 113, at least a portion of the semiconductor layer Act arranged below the gate electrode G may be exposed. The portion of the semiconductor layer Act, exposed by the insulating pattern layer 113a, may become conductive via plasma processing. The portion of the semiconductor layer Act, exposed by the insulating pattern layer 113a, may become conductive, and thus, the channel area C of the semiconductor layer Act may be formed.

The portion AT of the semiconductor layer Act arranged between the first opening portion OP1 and the first electrode E1 may be conductive, and thus, currents may flow along the portion AT of the semiconductor layer Act, a side of the first opening portion OP1 in an x direction, and the semiconductor layer Act adjacent to the first opening portion OP1. As described above, the first electrode E1 may be formed to be concave in the direction from the first opening portion OP1 toward the source area S or the drain area D of the semiconductor layer Act, and thus, the flow of currents from the portion AT of the semiconductor layer Act to the semiconductor layer Act adjacent to the first opening portion OP1 along the side of the first opening portion OP1 in the x direction may be improved.

In case that an edge of the first electrode E1 is formed as a straight line, an area of the opening portion of the semiconductor layer may be increased due to an error in a wet-etching process for forming the first electrode and wet-etching the semiconductor layer via etching of the material for forming the electrode. In case that the area of the opening portion of the semiconductor layer is increased, the flow of currents from the portion of the conductive semiconductor layer, the portion not being etched and remaining, to the semiconductor layer adjacent to the opening portion may be interrupted.

In case that the edge of the first electrode is formed to be concave in a direction from the opening portion of the semiconductor layer toward the source area or the drain area of the semiconductor layer, the semiconductor layer arranged below the insulating pattern layer adjacent to the opening portion of the semiconductor layer may also become conductive, in case that a portion of the semiconductor layer becomes conductive to form the channel area. Thus, the flow of currents from the portion of the conductive layer, the portion not being etched and remaining, to the semiconductor layer adjacent to the opening portion may be improved.

According to an embodiment as described above, a display apparatus for stably securing a conductive path for the electron or hole mobility in a semiconductor layer, and a method of manufacturing the display apparatus may be provided. However, the scope of the disclosure is not limited to these effects as described above.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure.

What is claimed is:

1. A display apparatus, comprising:
a semiconductor layer disposed on a substrate and including:
a channel area;
a source area and a drain area that are disposed at both sides of the channel area; and
a first opening portion disposed adjacent to the source area or the drain area; and
a first electrode overlapping and electrically connected to the source area or the drain area and including an edge adjacent to the first opening portion,
wherein the edge of the first electrode is concave in a direction from the first opening portion toward the source area or the drain area.

2. The display apparatus of claim 1, wherein the edge of the first electrode has an arc shape.

3. The display apparatus of claim 1, wherein
the edge of the first electrode includes:
a first sub-edge of the first electrode; and
a second sub-edge of the first electrode,
the first sub-edge of the first electrode and the second sub-edge of the first electrode extend in a first direction and a second direction, respectively, and
the first sub-edge of the first electrode and the second sub-edge of the first electrode intersect each other.

4. The display apparatus of claim 1, wherein an edge of the first opening portion that is adjacent to the first electrode is protrusive in a direction toward the source area or the drain area.

5. The display apparatus of claim 4, wherein the edge of the first opening portion that is adjacent to the first electrode has an arc shape.

6. The display apparatus of claim 4, wherein
the edge of the first opening portion that is adjacent to the first electrode includes:
a first sub-edge of the first opening portion; and
a second sub-edge of the first opening portion,
the first sub-edge of the first opening portion and the second sub-edge of the first opening portion extend in a first direction and a second direction, respectively, and
the first sub-edge of the first opening portion and the second sub-edge of the first opening portion intersect each other.

7. The display apparatus of claim 1, wherein a portion of the semiconductor layer is disposed between the edge of the first electrode and the first opening portion.

8. The display apparatus of claim 7, further comprising an insulating pattern layer disposed between the semiconductor layer and the first electrode.

9. The display apparatus of claim 8, wherein
the insulating pattern layer partially surrounds the first electrode, and
the first electrode partially overlaps the source area or the drain area of the semiconductor layer, and a portion of the semiconductor layer is exposed, due to the insulating pattern layer.

10. The display apparatus of claim 1, further comprising:
a second electrode overlapping and electrically connected to the source area or the drain area, wherein
the semiconductor layer further includes a second opening portion disposed adjacent to the source area or the drain area, and
an edge of the second electrode is concave in a direction from the second opening portion toward the source area or the drain area.

11. A method of manufacturing a display apparatus, the method comprising:
forming, on a substrate, a semiconductor layer including a channel area, and a source area and a drain area at both sides of the channel area;
forming, on the semiconductor layer, a material for forming an electrode;
forming a first photoresist on the material for forming the electrode; and
forming a first electrode by etching the material for forming the electrode, wherein
in case that the material for forming the electrode is etched, at least a portion of the semiconductor layer is etched resulting in a first opening portion being formed at a location adjacent to the source area or the drain area, and
an edge of the first electrode is formed to be concave in a direction from the first opening portion toward the source area or the drain area.

12. The method of claim 11, further comprising:
after the forming of the first electrode by etching the material for forming the electrode, removing the first photoresist.

13. The method of claim 11, wherein the edge of the first electrode has an arc shape.

14. The method of claim 11, wherein
the edge of the first electrode includes:
a first sub-edge of the first electrode; and
a second sub-edge of the first electrode,
the first sub-edge of the first electrode and the second sub-edge of the first electrode extend in a first direction and a second direction, respectively, and
the first sub-edge of the first electrode and the second sub-edge of the first electrode intersect each other.

15. The method of claim 11, wherein an edge of the first photoresist is formed to be concave in a direction from the channel area of the semiconductor layer toward the source area or the drain area of the semiconductor layer.

16. The method of claim 15, wherein the edge of the first photoresist has an arc shape.

17. The method of claim 15, wherein
the edge of the first photoresist includes:
a first sub-edge of the first photoresist; and
a second sub-edge of the first photoresist,
the first sub-edge of the first photoresist and the second sub-edge of the first photoresist extend in a first direction and a second direction, respectively, and
the first sub-edge of the first photoresist and the second sub-edge of the first photoresist intersect each other.

18. The method of claim 11, wherein
the forming of the semiconductor layer including the source area and the drain area includes:
forming, on the substrate, a material for forming a semiconductor layer;
forming the semiconductor layer by patterning the material for forming the semiconductor layer;
forming an inorganic insulating layer on the semiconductor layer; and
forming a plurality of holes by etching at least a portion of the inorganic insulating layer, and
in case that the plurality of holes are formed, an exposed portion of the semiconductor layer becomes conductive.

19. The method of claim 18, further comprising:
forming an insulating pattern layer by etching the inorganic insulating layer disposed between the semiconductor layer and the first electrode.

20. The method of claim 11, further comprising:
forming a second photoresist on the material for forming the electrode; and
forming, on the semiconductor layer, a second electrode by etching the material for forming the electrode, wherein
in case that the material for forming the electrode is etched, at least a portion of the semiconductor layer is etched resulting in a second opening portion being formed at a location adjacent to the source area or the drain area, and
an edge of the second electrode is formed to be concave in a direction from the second opening portion toward the source area or the drain area.
